(19) United States
(12) Patent Application Publication
(10) Pub. No.: US 2022/0149073 A1
(43) Pub. Date: May 12, 2022

(54) THREE-DIMENSIONAL FLASH MEMORY AND METHOD FOR MANUFACTURING SAME

(71) Applicant: Samsung Electronics Co., Ltd., Suwon-si (KR)

(72) Inventor: Yunheub Song, Seoul (KR)

(21) Appl. No.: 17/436,684

(22) PCT Filed: Apr. 2, 2020
(86) PCT No.: PCT/KR2020/004488

§ 371 Date: Sep. 7, 2021

(30) Foreign Application Priority Data
Apr. 4, 2019 (KR) 10-2019-0039735
Apr. 23, 2019 (KR) 10-2019-0047209
May 17, 2019 (KR) 10-2019-0057816

(51) Int. Cl. H01L 27/11582; H01L 27/11519; H01L 27/11565; H01L 27/11556; G11C 16/04

(52) U.S. Cl. CPC H01L 27/11582; H01L 27/11519; G11C 16/0483; H01L 27/11556; H01L 27/11565

(57) ABSTRACT

A three-dimensional flash memory and a method of manufacturing the three-dimensional flash memory are provided. The three-dimensional flash memory may have a structure for achieving integration, and may be manufactured using a manufacturing method for efficiently forming word lines.

### TECHNICAL FIELD

Embodiments below relate to a three-dimensional flash memory and a method of manufacturing the same.

### BACKGROUND ART

A flash memory is an electrically erasable and programmable read-only memory (EEPROM), and input and output of data thereof is electrically controlled by F-N tunneling (Fowler-Nordheim tunneling) or hot electron injection.

In recent flash memories, a three-dimensional structure has been applied, in which cells are vertically stacked to increase the degree of integration in order to provide high performance and realize low price demanded by consumers. Referring to FIGS. 1 and 2 showing a three-dimensional flash memory according to the related art, a three-dimensional flash memory 100 has a structure including at least one memory cell string 110 including a channel layer 111 extending in a vertical direction and a charge storage layer 112 formed to surround the channel layer 111, a plurality of electrode layers 120 connected to the at least one memory cell string 110 and stacked in a horizontal direction, and a plurality of insulating layers 130 alternately formed between the plurality of electrode layers 120. Hereinafter, as each of the plurality of electrode layers 120 is used as a word line, the plurality of electrode layers 120 will be described as a plurality of word lines 120.

Here, a contact 121 to be connected to an external wiring is to be formed on each of the plurality of word lines 120, and thus, the plurality of word lines 120 have a stair structure including a stepped portion 122 and a plane portion 123 as illustrated.

Here, only the contacts 121 of the plurality of word lines 120 are respectively formed in the stepped portion 122, and only the at least one memory cell string 110 is formed in the plane portion 123. That is, the at least one memory cell string 110 having a memory function is to be formed only on the plane portion 123, and thus, a significant amount of the area of the three-dimensional flash memory 100 is wasted. Furthermore, the higher the number of steps of the three-dimensional flash memory 100, the higher a ratio of an area of the stepped portion 122 with respect to the total memory area, thus reducing the overall degree of integration.

Accordingly, there is a need to propose a three-dimensional flash memory technique for improving the degree of integration by efficiently using the stepped portion 122.

In addition, the contacts 121 of the plurality of word lines 120 are respectively formed over the total, step-shaped area of the plurality of word lines 120, and thus, a significant amount of the area of the three-dimensional flash memory 100 is wasted. Furthermore, the higher the number of steps of the three-dimensional flash memory 100, the higher a ratio of an area of the contacts 121 with respect to the total memory area, thus reducing the overall degree of integration.

Accordingly, there is a need to propose a three-dimensional flash memory technique for achieving integration by reducing an area for forming contacts.

Referring to FIGS. 10A through 10D in regard to a method of manufacturing a three-dimensional flash memory according to the related art, according to the method, a photoresist 1030 is formed on a mold structure in which a plurality of word lines 1010 and a plurality of insulating layers 1020 are alternately stacked, and the photoresist 1030 is trimmed, as illustrated in FIG. 10A, and then, as illustrated in FIG. 10B, an etching operation is performed on an uppermost word line 1011 from among the plurality of word lines 1010 to form a portion of a stair shape. Next, in the method of manufacturing a three-dimensional flash memory according to the related art, the photoresist 1030 is trimmed, as illustrated in FIG. 10C, and then, as illustrated in FIG. 10D, an etching operation is performed on the word line 1011 and a word line 1012, surfaces of which are exposed, to form two portions having a stair shape. In the method of manufacturing a three-dimensional flash memory according to the related art, by repeating a trimming operation and an etching operation, as illustrated up to FIG. 10J and then removing the photoresist 1030, as illustrated in FIG. 10K, the word lines 1010 having a stair shape may be completed.

However, in the method of manufacturing a three-dimensional flash memory according to the related art, there is a disadvantage that the etching operation needs to be repeatedly performed one time less than the number of steps of the word lines 1010.

Accordingly, there is a need to propose a technique for simplifying the manufacturing process of word lines by reducing the number of repetitions of an etching operation.

### DESCRIPTION OF EMBODIMENTS

### Technical Problem

According to embodiments, a three-dimensional flash memory and a method of manufacturing the same to achieve integration by efficiently using a stepped portion are proposed.

In detail, according to embodiments, a three-dimensional flash memory in which at least one memory cell string is formed in both a plane portion and a stepped portion included in a stair shape of a plurality of word lines, and a method of manufacturing the three-dimensional flash memory are proposed.

In addition, according to embodiments, a three-dimensional flash memory and a method of manufacturing the same to achieve integration by reducing an area for forming contacts are proposed.

In detail, according to embodiments, a three-dimensional flash memory in which a contact of each of the plurality of word lines is formed only in a minimized partial area of the entire region of each of the plurality of word lines, and a method of manufacturing the three-dimensional flash memory are proposed.

In addition, according to embodiments, a method of manufacturing a three-dimensional flash memory is proposed, wherein the manufacturing process is simplified by reducing the number of repetitions of an etching operation on a word line.

In detail, according to embodiments, a method of manufacturing a three-dimensional flash memory is proposed, wherein a plurality of word lines are prepared by dividing the plurality of word lines into an upper word line group and a lower word line group that are sequentially stacked in a stair shape and then an etching operation is simultaneously performed on each of the upper word line group and the lower word line group to thereby remarkably reduce the number of repetitions of the etching operation on the word lines.

In addition, according to embodiments, a three-dimensional flash memory manufactured according to the method of manufacturing a three-dimensional flash memory, described above, is proposed.

In detail, according to embodiments, a three-dimensional flash memory having a structure including a portion having a different height from other portions in a stair shape while forming the stair shape having an equally spaced width and an equally spaced height by using a plurality of word lines is proposed.

In addition, according to embodiments, a three-dimensional flash memory having a structure including a portion having a different width from other portions in a stair shape while forming the stair shape having an equally spaced width and an equally spaced height by using a plurality of word lines is proposed.

In addition, according to embodiments, a three-dimensional flash memory having a structure including a portion having a different height and a portion having a different width from other portions in a stair shape while forming the stair shape having an equally spaced width and an equally spaced height by using a plurality of word lines is proposed.

### Solution to Problem

According to an embodiment, a three-dimensional flash memory for achieving integration, includes: at least one memory cell string extending vertically and including at least one channel layer and at least one charge storage layer surrounding the at least one channel layer; and a plurality of word lines that are orthogonally connected to the at least one memory cell string and stacked and extend in a horizontal direction, wherein the plurality of word lines extend by different lengths from each other to form a stair shape including a stepped portion and a plane portion, wherein the at least one memory cell string is formed both in the plane portion and the stepped portion.

A contact of each of the plurality of word lines may be formed only in a minimized partial region of each of a plurality of steps of the stepped portion.

The minimized partial region may include a region corresponding to a cross-sectional area of the contact of each of the plurality of word lines.

The at least one memory cell string formed in the stepped portion may be located in a same column as a contact of each word line, formed in the stepped portion, for each of steps of the stepped portion.

According to an embodiment, a three-dimensional flash memory for achieving integration, includes: at least one memory cell string extending in a direction and including at least one channel layer and at least one charge storage layer surrounding the at least one channel layer; and a plurality of word lines vertically connected to the at least one memory cell string, wherein a contact of each of the plurality of word lines is formed only in a minimized partial region of the entire region of each of the plurality of word lines.

The plurality of word lines may provide a space where at least one another memory cell string that is not arranged in a same array as the at least one memory cell string is formed, as the contact of each of the plurality of word lines is formed only in a minimized partial region of the entire region of each of the plurality of word lines.

The plurality of word lines may be shared by the at least one memory cell string and the at least one another memory cell string as the at least one another memory cell string is formed in the space.

The minimized partial region where the contact of each of the plurality of word lines is formed may include a region located in a same row as the entire region of each of the plurality of word lines.

According to an embodiment, a method of manufacturing a three-dimensional flash memory, for efficiently forming word lines, includes: preparing a plurality of word lines stacked in a horizontal direction by dividing the plurality of word lines into an upper word line group and a lower word line group, wherein the upper word line group and the lower word line group have different horizontal sizes and are stacked in order in a stair shape such that at least a portion of an upper surface of each of the upper and lower word line groups is exposed; forming photoresists on at least a portion of the upper surface of the upper word line group and at least a portion of the upper surface of the lower word line group; and simultaneously performing an etching operation on each of the upper word line group and the lower word line group, on which the photoresists are formed.

The lower word line group may have a greater horizontal size than the upper word line group.

The preparing of the plurality of word lines by dividing the plurality of word lines into an upper word line group and a lower word line group may include determining a horizontal size of the lower word line group to include an etch stopper distance to prevent etching of a lowermost word line of the upper word line group when an etching operation is performed on the lower word line group.

The preparing of the plurality of word lines by dividing the plurality of word lines into an upper word line group and a lower word line group may include arranging an etch stopper protection layer between the upper word line group and the lower word line group to prevent etching of an uppermost word line of the lower word line group when an etching operation is performed on the upper word line group.

The simultaneously performing of an etching operation on each of the upper word line group and the lower word line group may be repeatedly performed based on a number of steps whereby word lines included in the upper word line group are stacked and a number of steps whereby word lines included in the lower word line group are stacked.

### Advantageous Effects of Disclosure

According to embodiments, a three-dimensional flash memory and a method of manufacturing the same to achieve integration by efficiently using a stepped portion may be proposed.

In detail, according to embodiments, a three-dimensional flash memory in which at least one memory cell string is formed in both a plane portion and a stepped portion included in a stair shape of a plurality of word lines, and a method of manufacturing the three-dimensional flash memory may be proposed.

In addition, according to embodiments, a three-dimensional flash memory and a method of manufacturing the same to achieve integration by reducing an area for forming contacts may be proposed.

In detail, according to embodiments, a three-dimensional flash memory in which a contact of each of the plurality of word lines is formed only in a minimized partial area of the entire region of each of the plurality of word lines, and a method of manufacturing the three-dimensional flash memory may be proposed.

In addition, according to embodiments, a method of manufacturing a three-dimensional flash memory, in which the manufacturing process is simplified by reducing the number of repetitions of an etching operation on a word line may be proposed.

In detail, according to embodiments, a method of manufacturing a three-dimensional flash memory may be proposed, according to which a plurality of word lines are prepared by dividing the plurality of word lines into an upper word line group and a lower word line group that are sequentially stacked in a stair shape and then an etching operation is simultaneously performed on each of the upper word line group and the lower word line group to thereby remarkably reduce the number of repetitions of the etching operation on the word lines.

In addition, according to embodiments, a three-dimensional flash memory manufactured according to the method of manufacturing a three-dimensional flash memory, described above, may be proposed.

In detail, according to embodiments, a three-dimensional flash memory having a structure including a portion having a different height from other portions in a stair shape while forming the stair shape having an equally spaced width and an equally spaced height by using a plurality of word lines may be proposed.

In addition, according to embodiments, a three-dimensional flash memory having a structure including a portion having a different width from other portions in a stair shape while forming the stair shape having an equally spaced width and an equally spaced height by using a plurality of word lines may be proposed.

In addition, according to embodiments, a three-dimensional flash memory having a structure including a portion having a different height and a portion having a different width from other portions in a stair shape while forming the stair shape having an equally spaced width and an equally spaced height by using a plurality of word lines may be proposed.

### BRIEF DESCRIPTION OF THE DRAWINGS

FIG. 1 is a plan view of a three-dimensional flash memory according to the related art.

FIG. 2 is a cross-sectional view of a three-dimensional flash memory according to the related art.

FIG. 3 is a plan view of a three-dimensional flash memory according to an embodiment.

FIG. 4 is a cross-sectional view of a three-dimensional flash memory according to an embodiment.

FIG. 5 is a flowchart of a method of manufacturing a three-dimensional flash memory, according to an embodiment.

FIGS. 6A through 6I are diagrams for describing a method of manufacturing a three-dimensional flash memory according to an embodiment.

FIG. 7 is a plan view of a three-dimensional flash memory according to an embodiment.

FIGS. 8A and 8B are cross-sectional views of a three-dimensional flash memory according to an embodiment.

FIG. 9 is a flowchart of a method of manufacturing a three-dimensional flash memory, according to an embodiment.

FIGS. 10A through 10K are diagrams for describing a method of manufacturing a three-dimensional flash memory, according to the related art.

FIG. 11 is a flowchart of a method of manufacturing a three-dimensional flash memory, according to an embodiment.

FIGS. 12A through 12K are diagrams for describing a method of manufacturing a three-dimensional flash memory, according to an embodiment.

FIGS. 13A through 13C illustrate a three-dimensional flash memory manufactured using the method of manufacturing a three-dimensional flash memory, described with reference to FIG. 11.

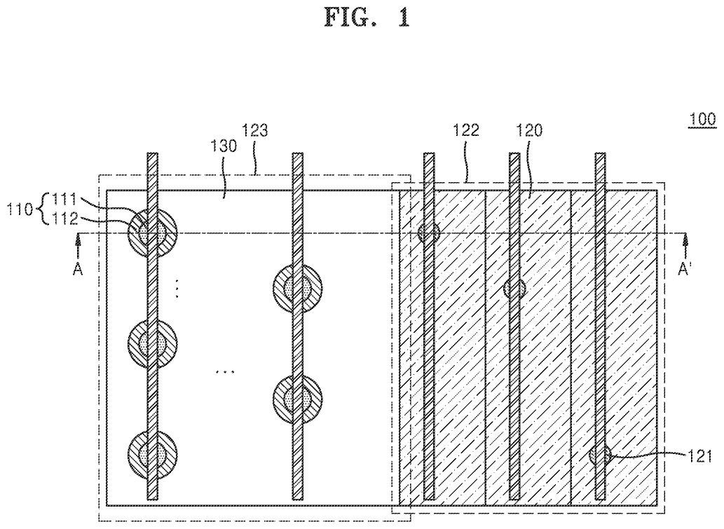

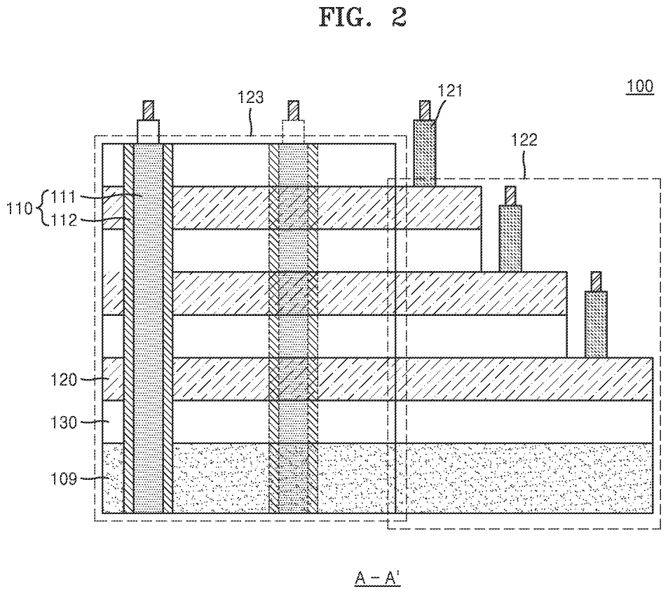

### BEST MODE

Hereinafter, embodiments will be described in detail with reference to the accompanying drawings. However, the inventive concept is not limited by the embodiments. In addition, like reference numerals shown in each drawing denote like elements.

The terminology used in this specification are those terminology used to appropriately express embodiments of the inventive concept, and the terminology may vary according to the intention of those of ordinary skill in the art, precedents, or customs. Thus, the terms used in the specification should be defined based on the description of the inventive concept.

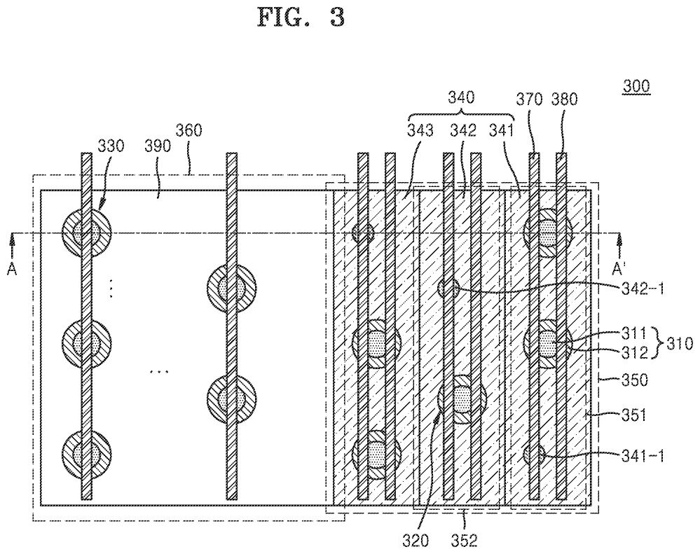

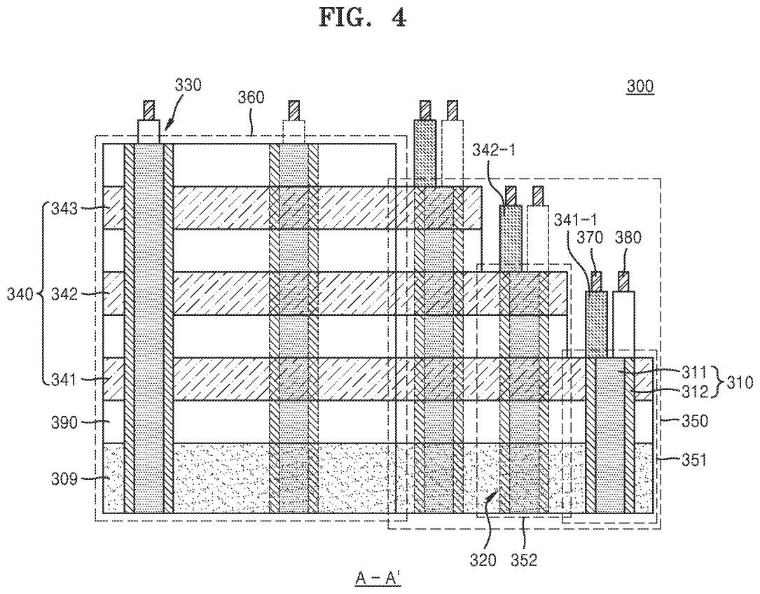

FIG. 3 is a plan view of a three-dimensional flash memory according to an embodiment, and FIG. 4 is a cross-sectional view of a three-dimensional flash memory according to an embodiment.

Referring to FIGS. 3 and 4, a three-dimensional flash memory 300 may include at least one memory cell string 310, 320, 330 extending vertically and a plurality of word lines 340 that are orthogonally connected to the at least one memory cell string 310, 320, 330 and are stacked and extend in a horizontal direction.

The at least one memory cell string 310, 320, 330 may include at least one channel layer 311 and at least one charge storage layer 312 surrounding the at least one channel layer 311. The at least one channel layer 311 may include single crystal silicon or poly-silicon extending in a vertical direction, and may be formed using a selective epitaxial growth process or a phase-change epitaxial process in which a substrate (not shown) is used as a seed. Also, the at least one channel layer 311 may have a hollow tube shape and further include a buried layer (not shown) therein.

The at least one charge storage layer 312 may include an element having a memory function of storing charges from a current flowing through the plurality of word lines 340, and may have, for example, an oxide-nitride-oxide (ONO) structure. Hereinafter, while the at least one charge storage layer 312 is described as including only a vertical element, the inventive concept is not limited thereto, and the at least one charge storage layer 312 may further include a horizontal element.

Also, although not illustrated in the drawings, at least one tunneling insulating layer (not shown) surrounding the at least one memory cell string 310, 320, 330 and vertically extending may be arranged outside the at least one memory cell string 310, 320, 330. The at least one tunneling insulating layer may include an insulating material having high-k characteristics (for example, an insulating material such as Al₂O₃, HfO₂, TiO₂, La₂O₅, BaZrO₃, Ta₂O₅, ZrO₂, Gd₂O₃ or Y₂O₃).

The plurality of word lines 340 have a function of applying a voltage to the at least one memory cell string 310, 320, 330, and may include a conductive material such as W, Ti, Ta, Cu or Au. The plurality of word lines 340 may extend by different lengths from each other to form a stair shape including a stepped portion 350 and a plane portion 360. For example, from among the plurality of word lines 340, a first word line 341 in a lowermost portion may have a longest horizontal length, and a second word line 341 located above the first word line 341 may have a second longest horizontal length, and a third word line 343 in an uppermost portion may have a shortest horizontal length, thereby forming a stair shape including the stepped portion 350 and the plane portion 360.

In particular, the three-dimensional flash memory 300 according to the embodiment is characterized in that the at least one memory cell string 310, 320, 330 is formed both in the plane portion 360 and the stepped portion 350. For example, a first memory cell string 310 and a second memory cell string 320 may be formed in the stepped portion 350, and a third memory cell string 330 may be formed in the plane portion 360. Thus, unlike a three-dimensional flash memory according to the related art in which at least one memory cell string is formed only in the plane portion 360, the overall degree of integration of the three-dimensional flash memory 300 according to the embodiment may be improved.

Here, contacts 341-1, 342-1 of the plurality of word lines 340 may be formed only in a minimized partial region in each of a plurality of steps 351, 352 constituting the stepped portion 350. Hereinafter, the minimized partial region may refer to a region corresponding to a cross-sectional area of each of the contacts 341-1 and 341-2 of the plurality of word lines 340, for example, a region having an equal area to that of the cross-sectional area of each of the contacts 341-1 and 341-2 of the plurality of word lines 340, from among the overall area of each of the plurality of steps 351 and 352.

Also, the at least one memory cell string 310, 320 formed in the stepped portion 350 may be located in a same column as the contacts 341-1, 342-1 of the word lines 341, 342 formed in the stepped portion 350 for each of the plurality of steps 351 and 352 constituting the stepped portion 350. For example, the first memory cell string 310 formed in the step 351 of the first word line 341 and the contact 341-1 of the first word line 341 may be located in a same column, and the second memory cell string 320 formed in the step 352 of the second word line 342 and the contact 342-1 of the second word line 342 may be located in a same column.

As the at least one memory cell string 310, 320 formed in the stepped portion 350 is located in a same column as each contact 341-1, 342-1 of each of the word lines 341, 342 formed in the stepped portion 350 for each of the plurality of steps 351, 352 constituting the stepped portion 350, an external wiring 370 connected to each contact 341-1, 342-1 of the word lines 341, 342 formed in the stepped portion 350 and a drain line 380 connected to the at least one memory cell string 310, 320 formed in the stepped portion 350 may also be located in a same column.

Also, the three-dimensional flash memory 300 may further include a plurality of interlayer insulating layers 390 between the plurality of word lines 340. However, the inventive concept is not limited thereto, and instead of the plurality of interlayer insulating layers 380, a plurality of air gaps spacing the plurality of word lines 340 apart from each other may be arranged.

As described above, the three-dimensional flash memory 300 according to the embodiment may include the at least one memory cell string 310, 320 also in the stepped portion 350 of the plurality of word lines 340, and thus, may include more memory cell strings 310, 320, 330 than a structure according to the related art in which no memory cell string is formed in the stepped portion 350. Accordingly, the integration degree of the three-dimensional flash memory 300 may be remarkably increased.

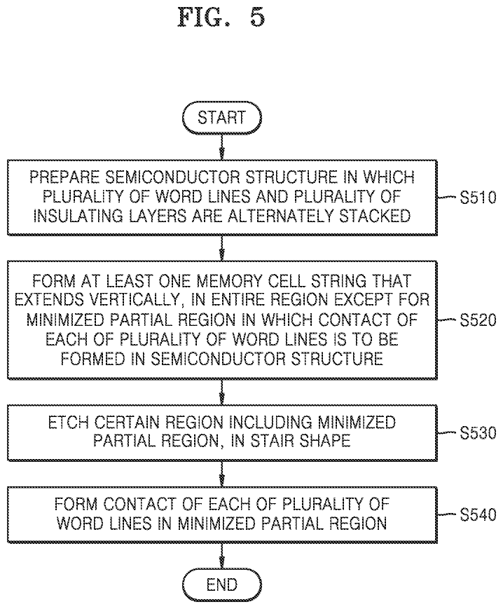

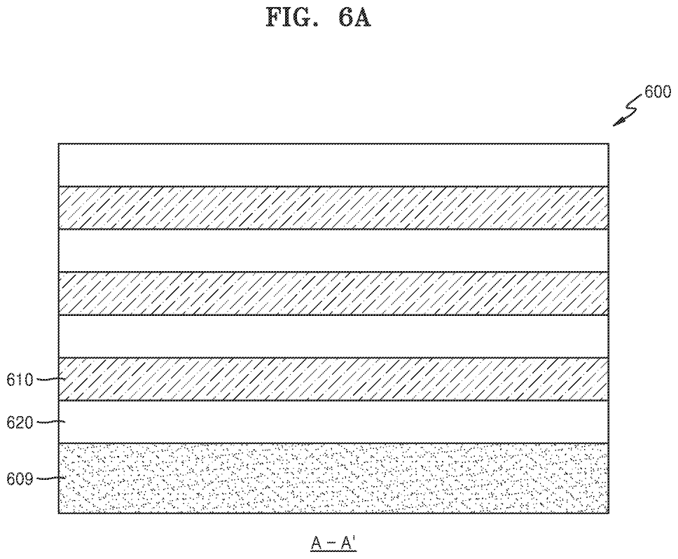

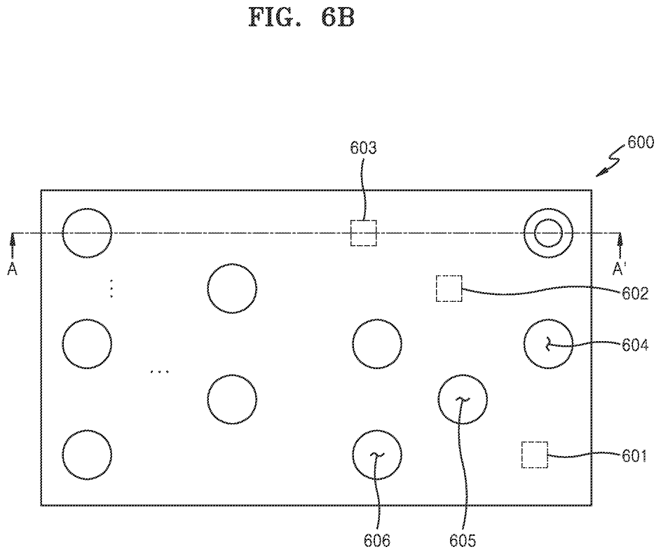

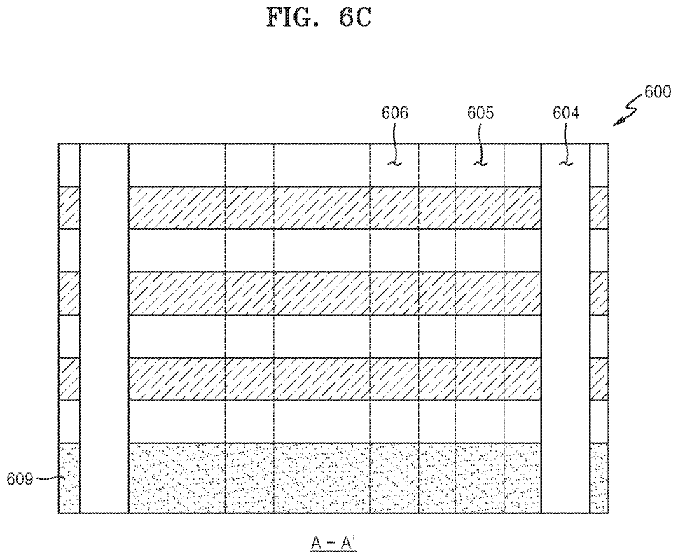

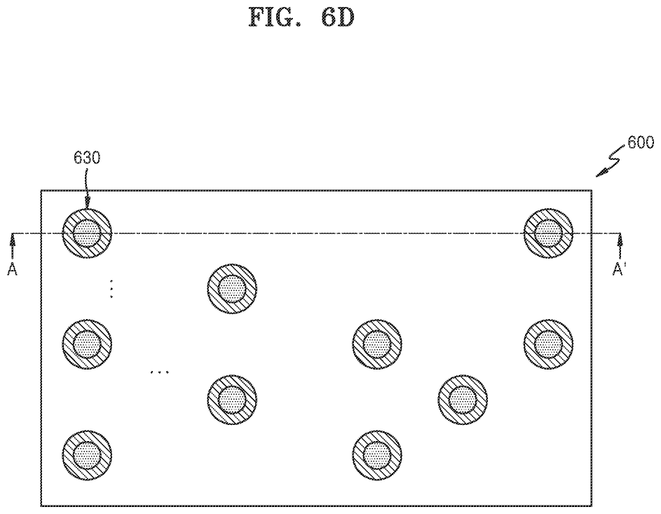

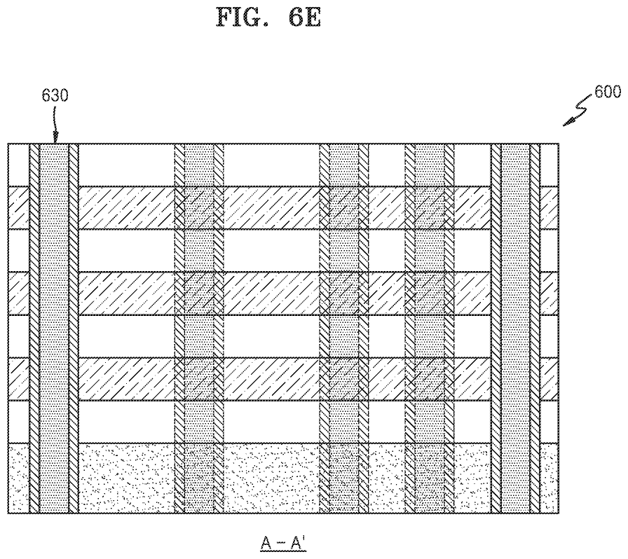

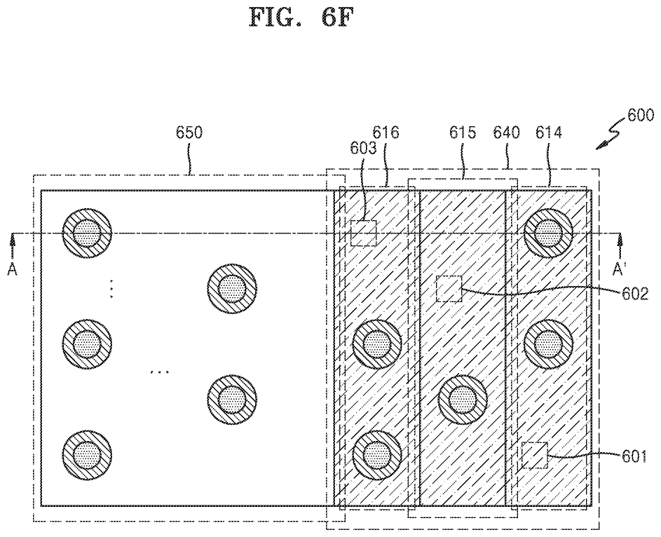

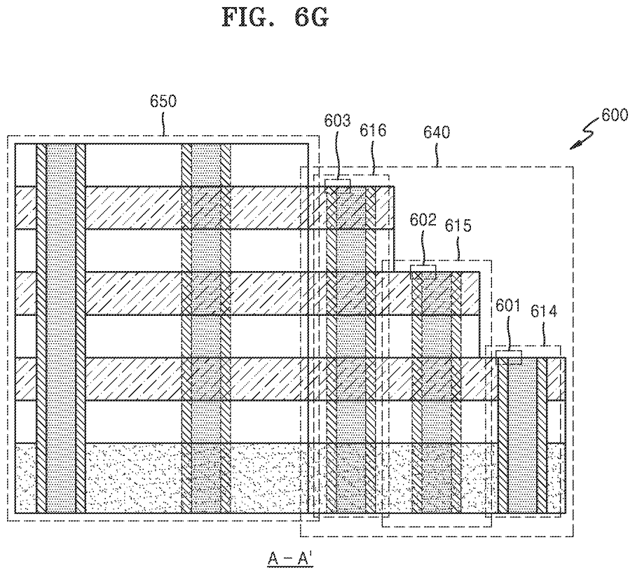

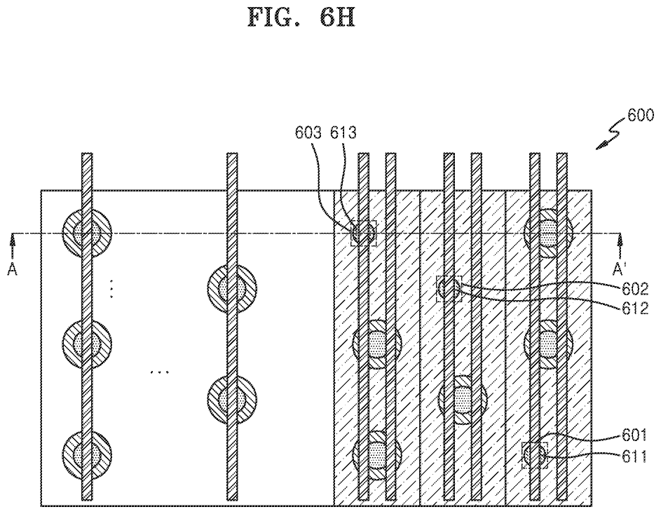

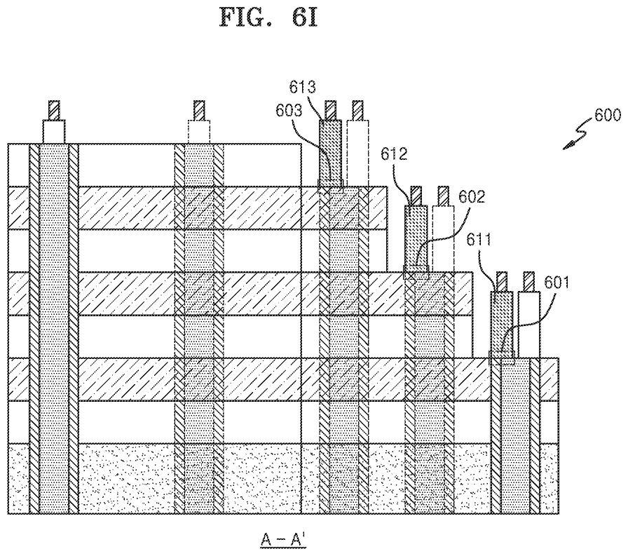

FIG. 5 is a flowchart of a method of manufacturing a three-dimensional flash memory, according to an embodiment. FIGS. 6A through 6I are diagrams for describing a method of manufacturing a three-dimensional flash memory according to an embodiment. Hereinafter, as a subject for performing the method of manufacturing a three-dimensional flash memory, an automated and mechanized manufacturing system may be used, and the three-dimensional flash memory manufactured in operations described below (S510 through S540) has the structure described with reference to FIGS. 3 and 4.

Referring to FIG. 5, the manufacturing system according to the embodiment prepares, in operation S510, a semiconductor structure 600 in which a plurality of word lines 610 and a plurality of insulating layers 620 are alternately stacked, as illustrated in FIG. 6A.

Next, in operation S520, the manufacturing system forms at least one memory cell string 630 (the at least one memory cell string 630 includes at least one channel layer and at least one charge storage layer surrounding the at least one channel layer) that extends vertically, in an entire region except minimized partial regions 601, 602, 603 in which contacts 611, 612, 613 of the plurality of word lines 610 are to be respectively formed in the semiconductor structure 600.

Hereinafter, the minimized partial regions 601, 602, 603 may refer to regions respectively corresponding to cross-sectional areas of the contacts 611, 612, 613 of the plurality of word lines 610, for example, regions having an equal area to cross-sectional areas of the contacts 611, 612, 613 of the plurality of word lines 610 of an entire region of each of a plurality of steps 614, 615, 616 to be included in a stair shape.

For example, the manufacturing system may form at least one vertical hole 604, 605, 606 in a vertical direction in an entire region except for the minimized partial regions 601, 602, 603 of the semiconductor structure 600 by considering an arrangement of the minimized partial regions 601, 602, 603 such that the minimized partial regions 601, 602, 603 are respectively included in the plurality of steps 614, 615, 616 to be included in a stair shape that the plurality of word lines 610 are to have, as illustrated in FIGS. 6B an 6C, and then form at least one memory cell string 630 in the at least one vertical hole 604, 605, 606, as illustrated in FIGS. 6D and 6E.

Here, in the operation of forming the at least one vertical hole 604, 605, 606, the manufacturing system may form the at least one vertical hole 604, 605, 606 for each of the plurality of steps 604, 605, 606 in a vertical direction such that the at least one vertical hole 604, 605, 606 is located in a same column as the minimized partial regions 601, 602, 603 respectively included in the plurality of steps 614, 615, 616 to be formed in operation S530 which will be described later.

Next, the manufacturing system etches a certain region including the minimized partial regions 601, 602, 603 in a stair shape, as illustrated in FIGS. 6F and 6G, in operation S530. For example, the manufacturing system may form a stair shape including a stepped portion 640 including a plurality of steps 614, 615, 616 and a plane portion 650 by etching the certain region including the minimized partial regions 601, 602, 603, in a stair shape.

Operation S530 may be performed by repeatedly performing a trimming operation and an etching operation based on the number of steps of the plurality of steps 614, 615, 616 to be formed, and an etching method used in operation S530 may be an etching method that allows to simultaneously etch the at least one memory cell string 630 and the plurality of word lines 610. That is, in operation S530, the manufacturing system may use an etching method allowing to simultaneously etch a material of the at least one memory cell string 630 and a material of the plurality of word lines 610 at an equal depth.

Next, the manufacturing system may form the respective contacts 611, 612, 613 of the plurality of word lines 610 in the minimized partial regions 601, 602, 603 as illustrated in FIGS. 6H and 6I, in operation S540. Here, the manufacturing system may form an external wiring connected to the respective contacts 611, 612, 613 of the plurality of word lines 610 and a drain line connected to the at least one memory cell string 630, at the same time as forming the contacts 611, 612, 613 of the plurality of word lines 610.

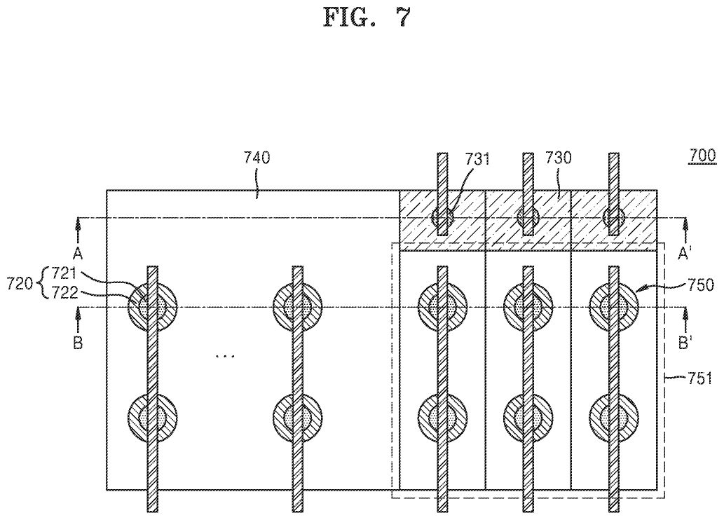

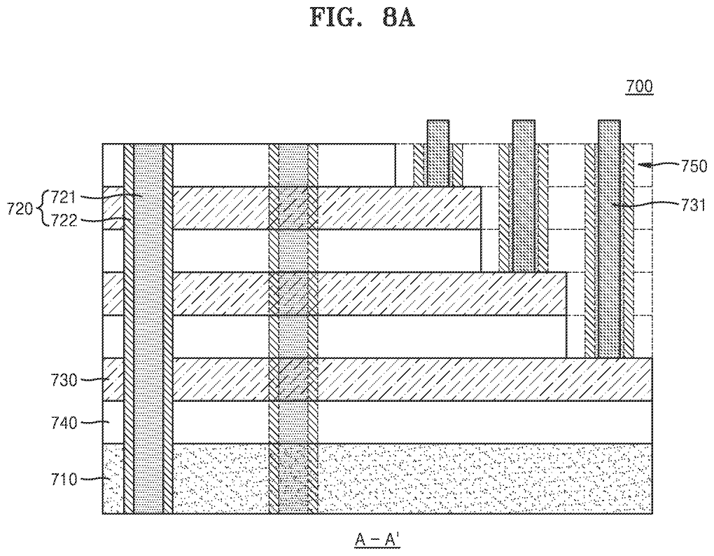

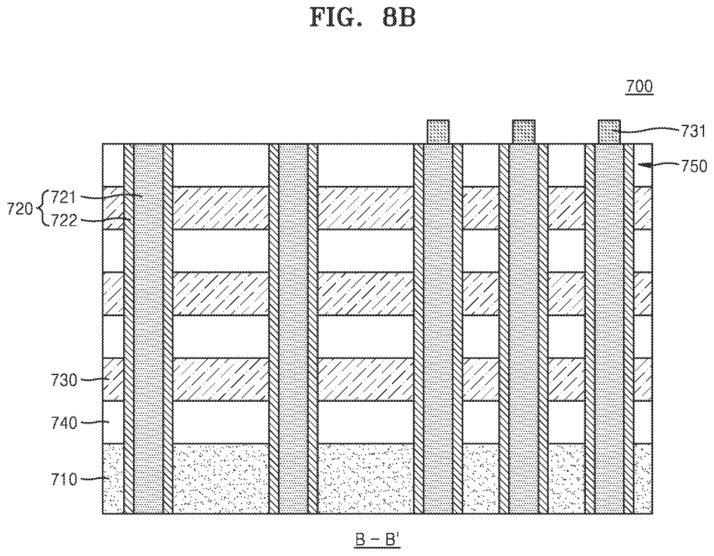

FIG. 7 is a plan view of a three-dimensional flash memory according to an embodiment, and FIGS. 8A and 8B are cross-sectionals view of a three-dimensional flash memory according to an embodiment.

Referring to FIGS. 7 through 8B, a three-dimensional flash memory 700 according to an embodiment includes, on a substrate 710, at least one memory cell string 720 extending in a direction and a plurality of word lines 730. In the three-dimensional flash memory 700, a drain line may be arranged on and connected to the at least one memory cell string 720, and each of the plurality of word lines 730 may be connected to an external wiring via a contact 731. Hereinafter, the drain line and the external wiring are illustrated only in FIG. 7, and are omitted in FIGS. 8A and 8B.

The at least one memory cell string 720 may include at least one channel layer 721 and at least one charge storage layer 722 surrounding the at least one channel layer 721. The at least one channel layer 721 may include single crystal silicon or poly-silicon, and may be formed using a selective epitaxial growth process or a phase-change epitaxial process in which the substrate 710 is used as a seed.

The at least one charge storage layer 722 may include an element storing charges from a current flowing through the plurality of word lines 730, and may have, for example, an oxide-nitride-oxide (ONO) structure. While the at least one charge storage layer 722 is described below as including only a vertical element extending in a direction orthogonal to the substrate 710, the inventive concept is not limited thereto, and the at least one charge storage layer 722 may further include a horizontal element that is parallel to and contacts the plurality of word lines 730.

The plurality of word lines 730 are connected to the at least one memory cell string 720 in a vertical direction and may be alternately arranged with respect to a plurality of insulating layers 740. The plurality of word lines 730 may include a conductive material such as tungsten, titanium, tantalum, and the plurality of insulating layers 740 may include various insulating materials.

The plurality of word lines 730 are formed in a stair shape, and may be connected to an external wiring via each contact 731 formed in the stair shape. In detail, the contacts 731 of the plurality of word lines 730 are characterized in that they are respectively formed only in a minimized partial region of the entire region of each of the plurality of word lines 730. The contact 731 of each of the plurality of word lines 730 formed in the minimized partial region as described below refers to the contact 731 formed only in an area corresponding to a cross-section of the contact 731 of the entire region of each of the plurality of word lines 730.

Also, the minimized partial region in which the contact 731 of each of the plurality of word lines 730 is formed may be a region located in a same row in the entire region of each of the plurality of word lines 730. That is, while the contact 731 is formed only in a region corresponding to a cross-section of the contact 731 of the entire region of each of the plurality of word lines 730, the contact 731 may be formed in a region located in a same row in each of the plurality of word lines 730.

As described above, as the contact 731 of each of the plurality of word lines 730 is formed only in the minimized partial region of the entire region of each of the plurality of word lines 730, a space 751 where at least one other memory cell string 750 that is not arranged in a same array as the at least one memory cell string 720 is formed may be provided. Thus, the three-dimensional flash memory 700 may include more memory cell strings 720, 750 and thus have a higher integration degree. A same array as the at least one memory cell string 720 below refers to a set of memory cell strings including the at least one memory cell string 720 and a memory cell string arranged in a same column as the at least one memory cell string 720, and thus, the at least one other memory cell string 750 that is not arranged in a same array as the at least one memory cell string 720 may refer to a memory cell string arranged in a different column from the at least one memory cell string 720.

Here, as the at least one other memory cell string 750 is formed in the space 751, the plurality of word lines 730 may be shared by the at least one memory cell string 720 and the at least one other memory cell string 750. Hereinafter, the plurality of word lines 730 being shared by the at least one memory cell string 720 and the at least one other memory cell string 750 indicate that the plurality of word lines 730 are used to supply a current to both the at least one memory cell string 720 and the at least one other memory cell string 750.

According to the three-dimensional flash memory 700 according to the embodiment, as the contact 731 of each of the plurality of word lines 730 is formed only in the minimized partial region of the entire region of each of the plurality of word lines 730 as described, the space 751 where the at least one other memory cell string 750 that is not arranged in a same array as the at least one memory cell string 720 is formed is provided, and accordingly, the three-dimensional flash memory 700 may include a large number of memory cell strings 720, 750. Accordingly, the integration degree of the three-dimensional flash memory 700 may be remarkably increased.

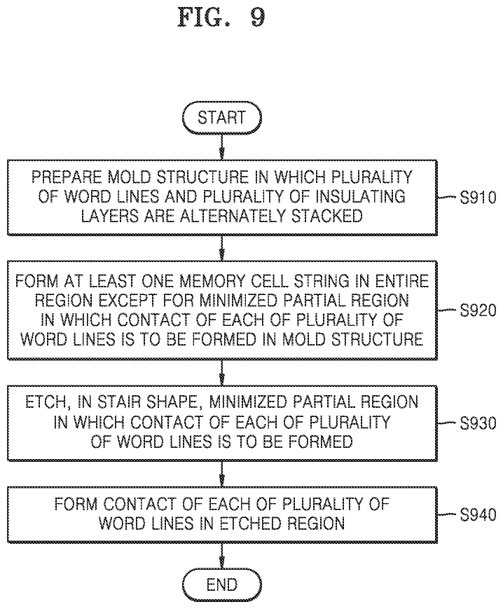

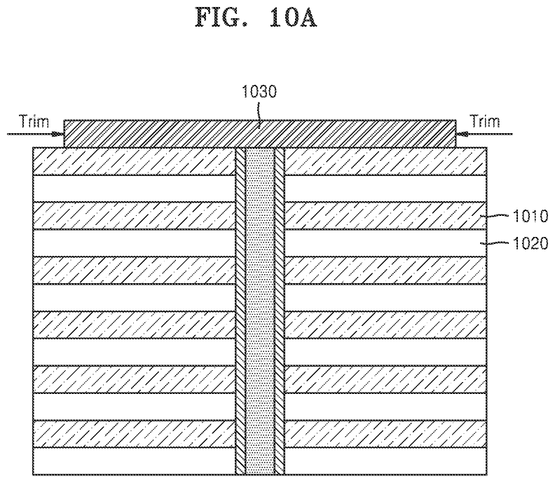

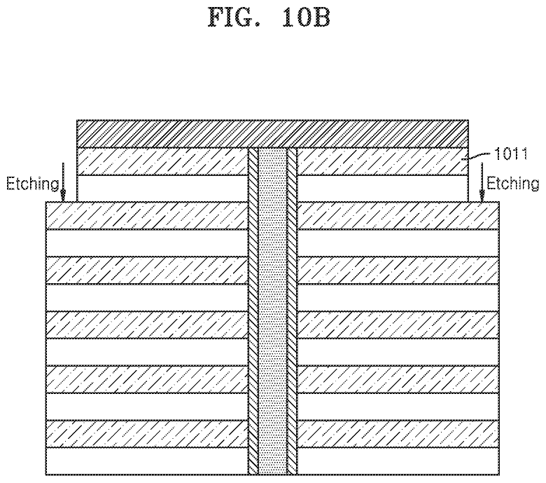

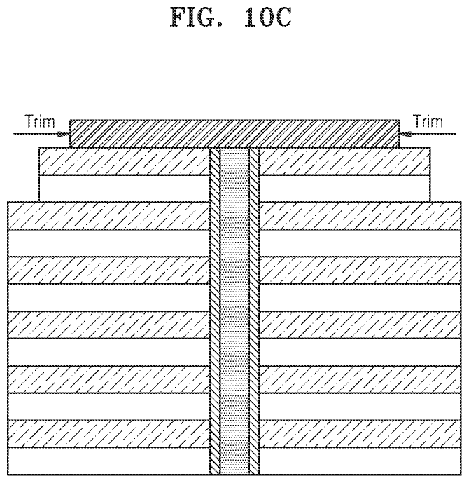

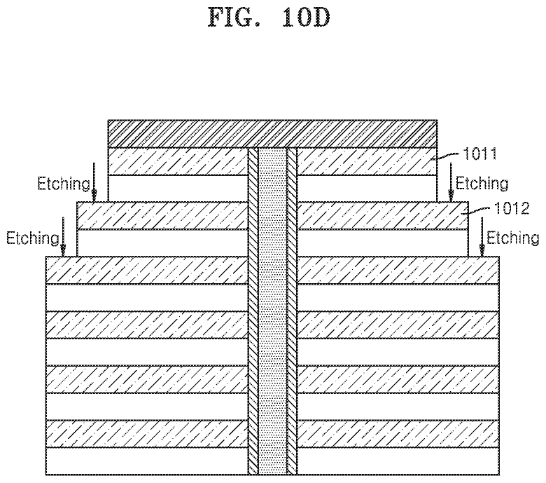

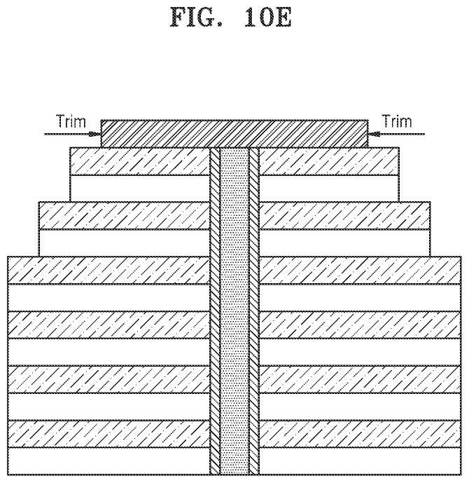

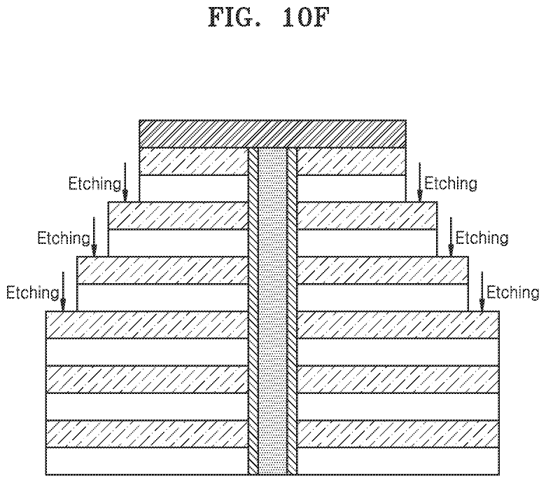

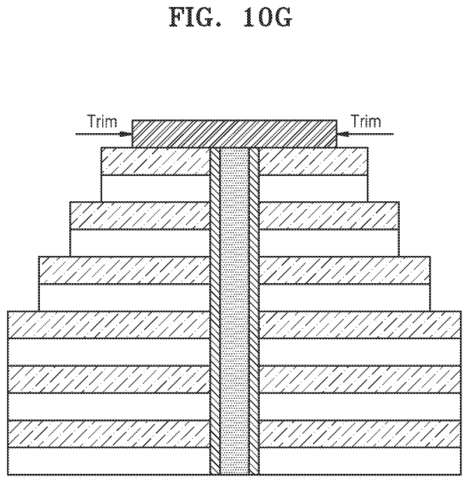

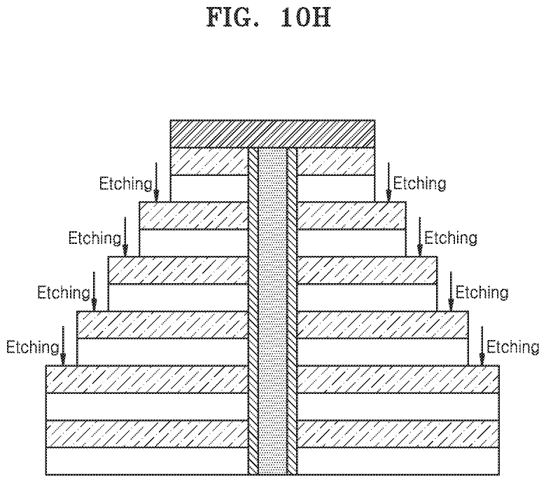

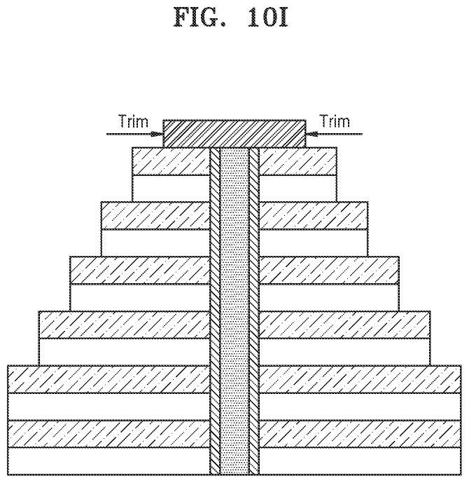

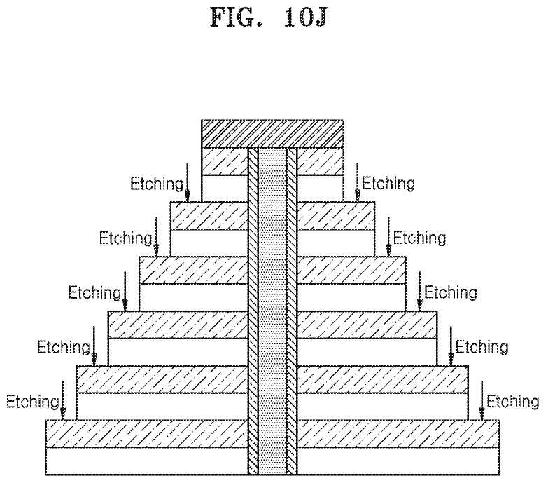

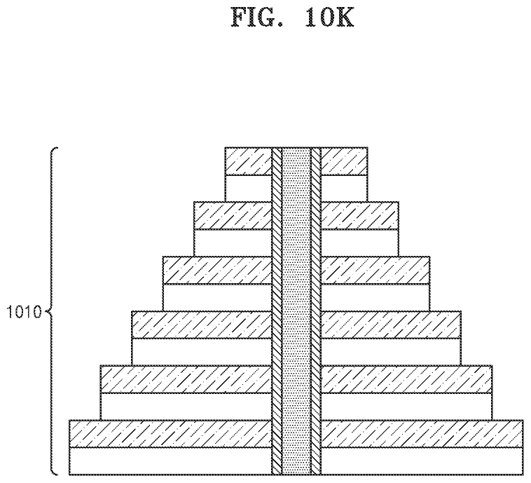

FIG. 9 is a flowchart of a method of manufacturing a three-dimensional flash memory, according to an embodiment. Hereinafter, as a subject for performing the method of manufacturing a three-dimensional flash memory, an automated and mechanized manufacturing system may be used, and the three-dimensional flash memory manufactured in operations described below (S910 through S940) has the structure described with reference to FIGS. 7 through 8B.

Referring to FIG. 9, the manufacturing system according to the embodiment prepares, in operation S910, a mold structure in which a plurality of word lines and a plurality of insulating layers are alternately stacked.

Next, in operation S920, the manufacturing system forms at least one memory cell string (the at least one memory cell string includes at least one channel layer and at least one charge storage layer surrounding the at least one channel layer) that extends in a direction in an area except a minimized partial region in which contacts of the plurality of word lines are to be formed in the mold structure.

For example, the manufacturing system may form a vertical hole in the remaining region except the minimized partial region where a contact of each of the plurality of word lines is to be formed, such that a substrate included in the mold structure is exposed, and then may deposit at least one charge storage layer in the vertical hole and fill at least one channel layer in the vertical hole to thereby form at least one memory cell string.

Here, the minimized partial region in which the contact of each of the plurality of word lines is to be formed may be a region corresponding to a cross-section of the contact of the entire region of each of the plurality of word lines, and may be a region located in a same row on the region of each of the plurality of word lines.

Also, in operation S920, to provide a space in which at least one other memory cell string that is not arranged in a same array as the at least one memory cell string is to be formed, the manufacturing system may form the at least one memory cell string extending in a direction, in the remaining region, and then form the at least one other memory cell string in the space in a direction.

Thus, in operation S920, the at least one other memory cell string may extend in a direction such that the plurality of word lines are shared between the at least one memory cell string and the at least one other memory cell string.

As described above, the manufacturing system leaves only the minimized partial region of the entire region of each of the plurality of word lines as a region for forming contacts in operation S920, and thus, may form memory cell strings in the entire region except the minimized partial region, thereby further improving the integration degree of the memory cell strings.

Next, in operation S930, the manufacturing system etches, in a stair shape, the minimized partial region in which a contact of each of the plurality of word lines is to be formed.

Next, the manufacturing system forms, in operation S940, a contact of each of the plurality of word lines in the etched region.

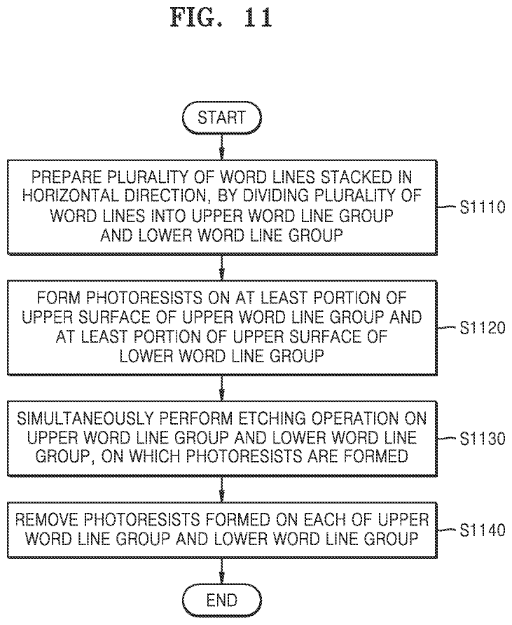

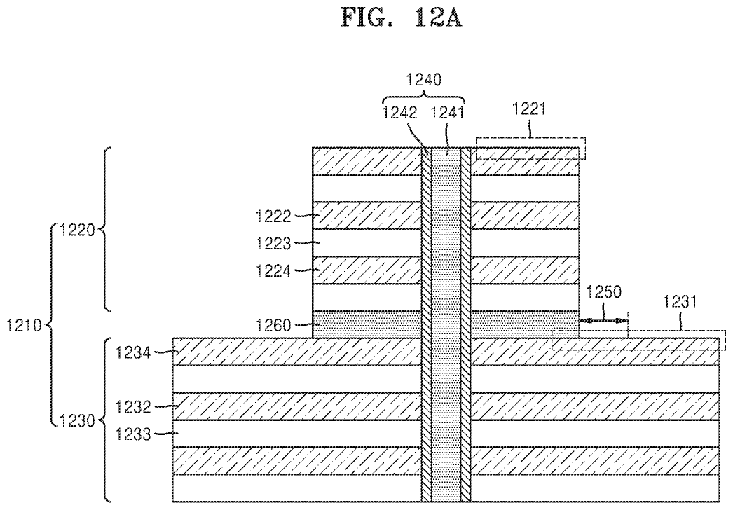

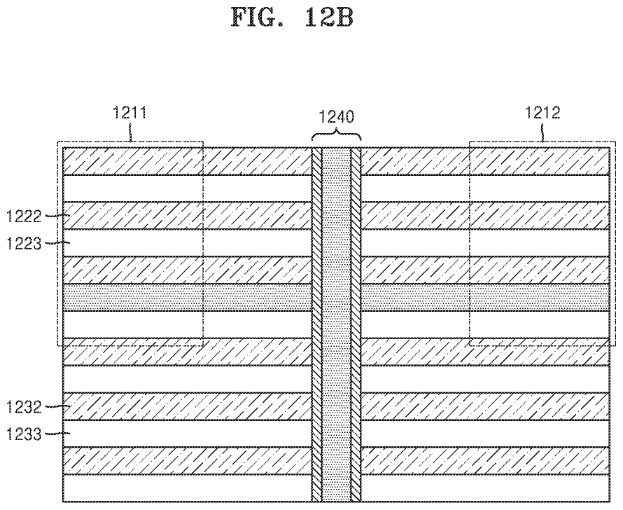

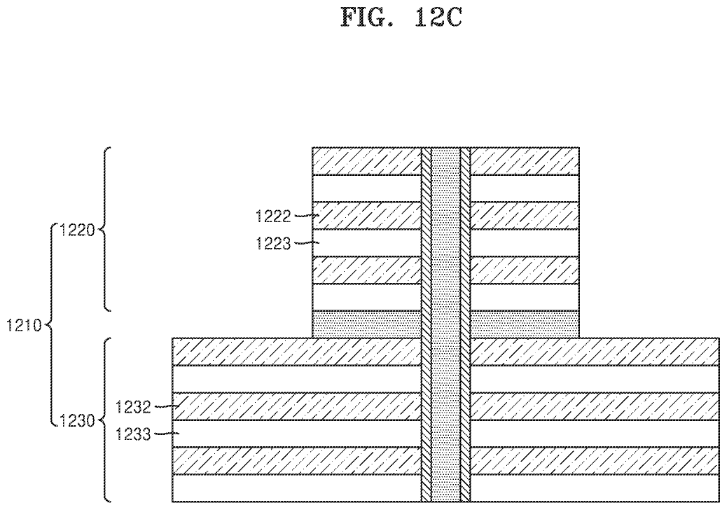

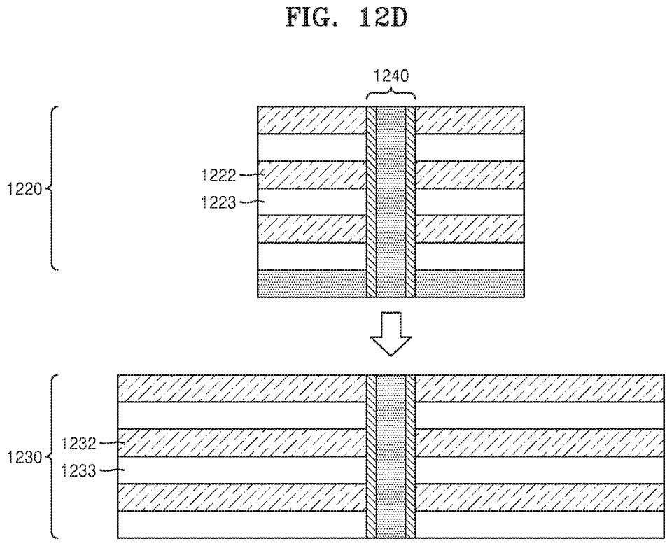

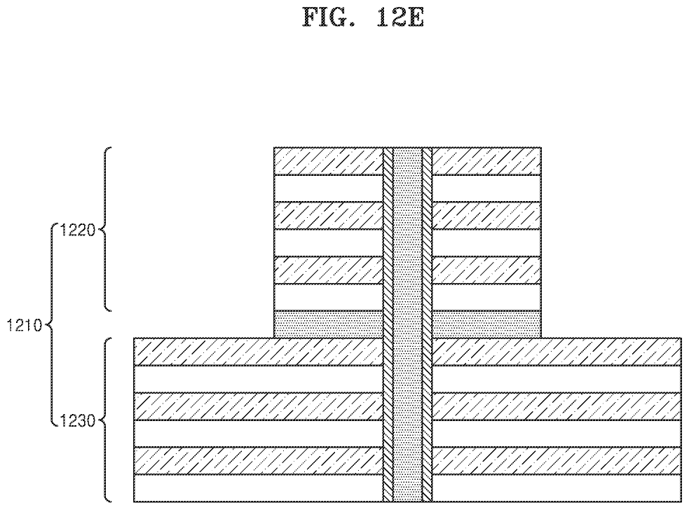

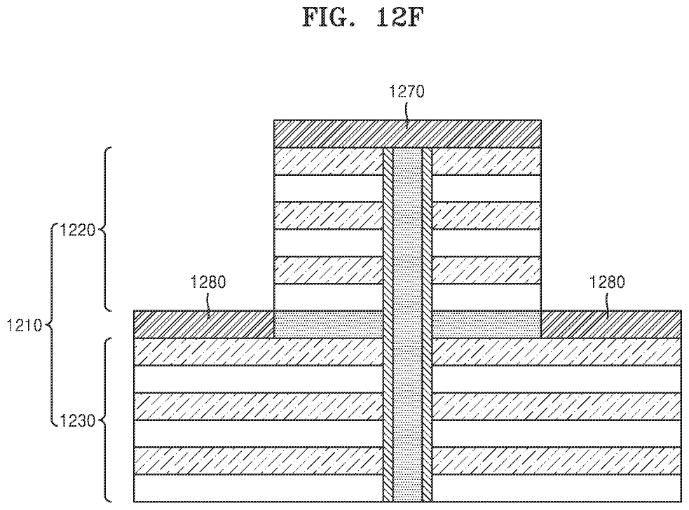

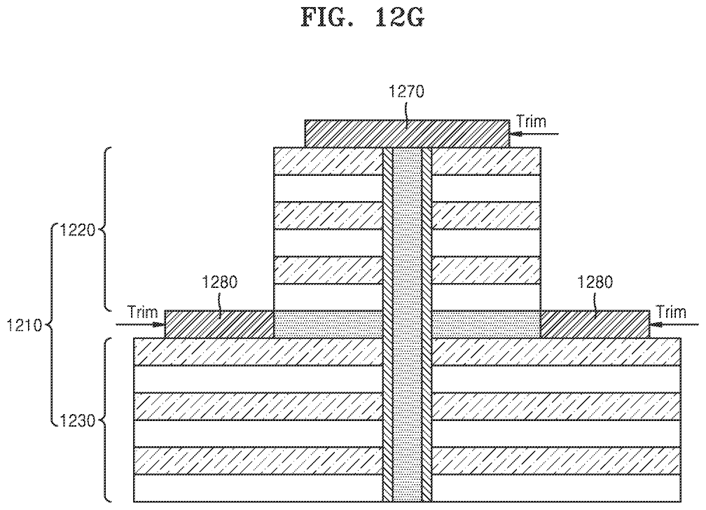

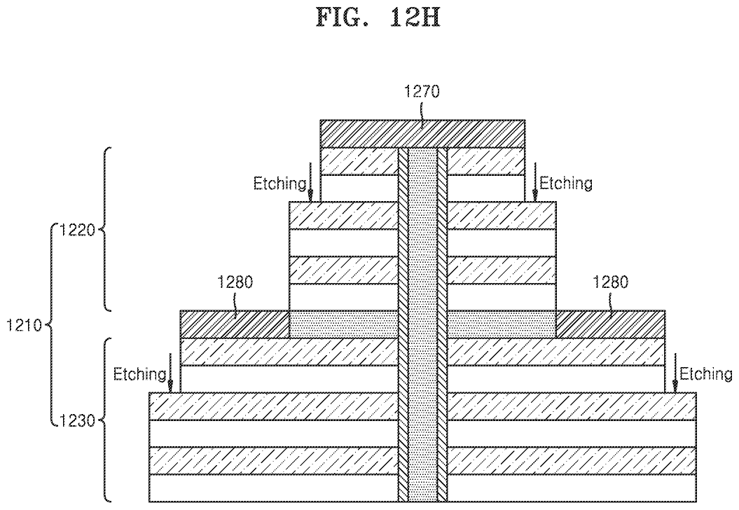

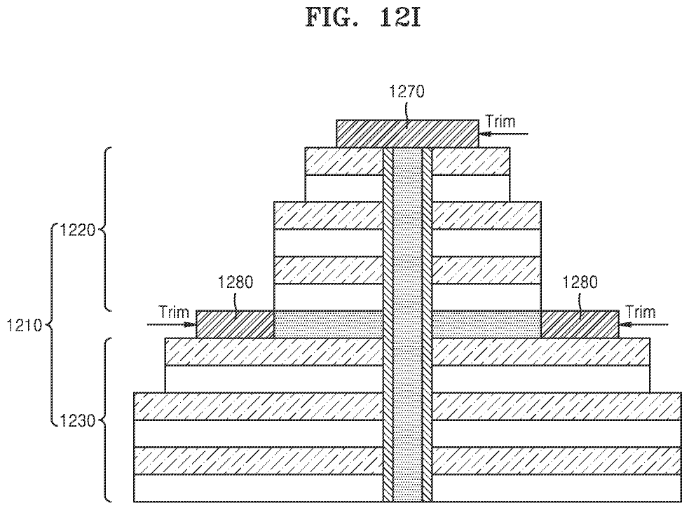

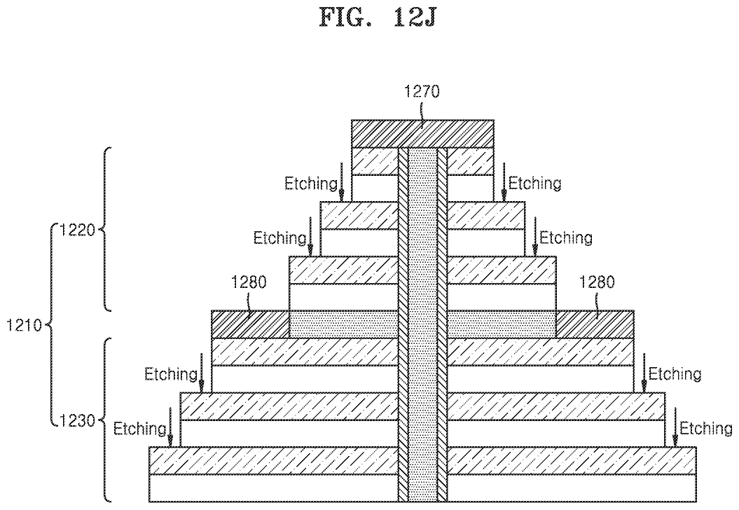

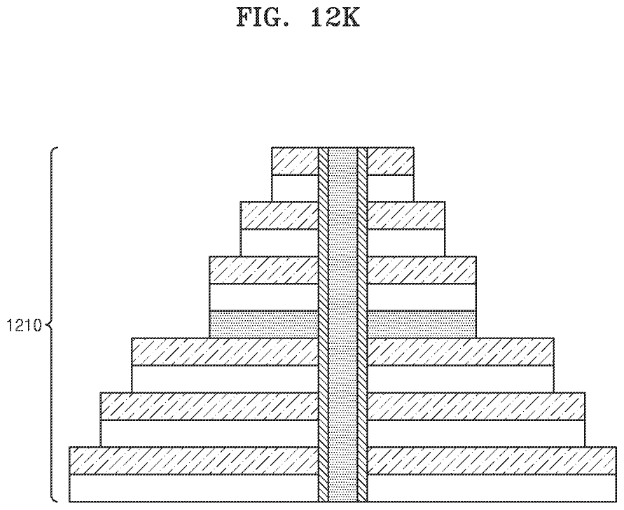

FIG. 11 is a flowchart of a method of manufacturing a three-dimensional flash memory, according to an embodiment. FIGS. 12A through 12K are diagrams for describing a method of manufacturing a three-dimensional flash memory, according to an embodiment. Hereinafter, as a subject for performing a method of manufacturing a three-dimensional flash memory, an automated and mechanized manufacturing system may be used.

Referring to FIGS. 11 through 12K, the manufacturing system prepares a plurality of word lines 1210 stacked in a horizontal direction by dividing them into an upper word line group 1220 and a lower word line group 1230 in operation S1110, as illustrated in FIG. 12A.

The upper word line group 1220 and the lower word line group 1230 may be prepared by stacking them with different horizontal sizes in order in a stair shape such that at least portions of upper surfaces 1221 and 1231 thereof are exposed. For example, the upper word line group 1220 and the lower word line group 1230 may be respectively provided by stacking them in order where the horizontal size of the lower word line group 1230 is greater than that of the upper word line group 1220 such that at least portions of the upper surfaces 1221, 1231 are exposed.

Here, operation S1110 refers to not only an operation of preparing just the plurality of word lines 1210 but an operation of preparing a mold structure including a plurality of insulating layers 1223, 1233 that are alternately included between the plurality of word lines 1210 and a vertical string 1240 including a channel layer 1241 and a charge storage layer 1242. Thus, the upper word line group 1220 may include upper word lines 1222 and upper insulating layers 1223 that are alternately included between the upper word lines 1222, and the lower word line group 1230 may include lower word lines 1232 and lower insulating layers 1233 that are alternately included between the lower word lines 1232, and the upper word line group 1220 and the lower word line group 1230 may share one vertical string 1240.

For example, in operation S1110, the manufacturing system may prepare the plurality of word lines 1210 having a step form and divided into the upper word line group 1220 and the lower word line group 1230, as illustrated in FIG. 12A, by etching portions 1211, 1212 of the mold structure in which the plurality of word lines 1222, 1232 and the plurality of insulating layers 1223, 1233 are alternately stacked and the vertical string 1240 is formed in a vertical direction, as illustrated in FIGS. 12B and 12C.

As another example, in operation S1110, the manufacturing system may prepare the plurality of word lines 1210 having a step form and divided into the upper word line group 1220 and the lower word line group 1230, as illustrated in FIG. 12A, by stacking an upper mold structure (in the upper mold structure, the upper word lines 1222 having a smaller horizontal size than the lower word lines 1232 and the upper insulating layers 1223 are alternately stacked and an upper vertical string is formed in a vertical direction) on a lower mold structure (in the lower mold structure, the lower word lines 1232 and the lower insulating layers 1233 are alternately stacked and a lower vertical string is formed in a vertical direction), as illustrated in FIGS. 12D and 12E.

In particular, in operation S1110, the manufacturing system may determine a horizontal size of the lower word line group 1230 to include an etch stopper distance 1250 to prevent a lowermost word line of the upper word line group 1220 from being etched when an etching operation is performed on the lower word line group 1230 in operation S1130 to be described later. This will be described in further detail below.

Also, in operation S1110, the manufacturing system may arrange an etch stopper protection layer 1260 between the upper word line group 1220 and the lower word line group 1230 to prevent an uppermost word line of the lower word line group 1230 from being etched when an etching operation is performed on the upper word line group 1220 in operation S1130 to be described later. This will also be described in further detail below.

Next, in operation 51120, the manufacturing system forms photoresists 1270, 1280 on at least a portion of an upper surface 1221 of the upper word line group 1220 and at least a portion of an upper surface 1231 of the lower word line group 1230, as illustrated in FIG. 12F.

Next, in operation S1130, the manufacturing system performs an etching operation simultaneously on the upper word line group 1220 and the lower word line group 1230, on which the photoresists 1270, 1280 are formed, as illustrated in FIG. 12H.

Here, before operation S1130, the manufacturing system may trim the photoresists 1270, 1280 by an equally spaced width that the stair shape, which is to be formed by the plurality of word lines 1210, is to have, as illustrated in FIG. 12G.

Operation S1130 may be repeatedly performed based on the number of steps whereby the upper word lines 1222 included in the upper word line group 1220 are stacked and the number of steps whereby the lower word lines 1232 included in the lower word line group 1230 are stacked, and a three-dimensional flash memory including the word lines 1210 having a stair shape may be manufactured, accordingly.

Likewise, while operation S1130 is repeatedly performed, the manufacturing system may additionally repeat the operation of trimming the photoresists 1270, 1280, as illustrated in FIGS. 12H through 12J, to thereby allow the word lines 1210 to have a stair shape.

As described above, as the horizontal size of the lower word line group 1230 is determined to include the etch stopper distance 1250, as illustrated in FIG. 12H, when an etching operation on the lower word line group 1230 is performed, mis-etching of the lowermost word line 1224 of the upper word line group 1220 may be prevented.

Also, as described above, as the etch stopper protection layer 1260 is between the upper word line group 1220 and the lower word line group 1230, as illustrated in FIG. 12H, when an etching operation is performed on the upper word line group 1220, mis-etching of an uppermost word line 1234 of the lower word line group 1230 may be prevented.

While both determining the horizontal size of the lower word line group 1230 to include the etch stopper distance 1250 and arranging the etch stopper protection layer 1260 between the upper word line group 1220 and the lower word line group 1230 are described to be performed in operation S1110, the inventive concept is not limited thereto, and any one of them may also be performed.

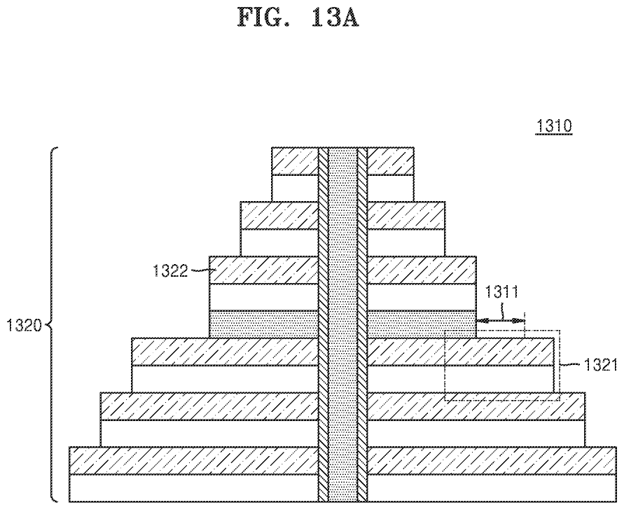

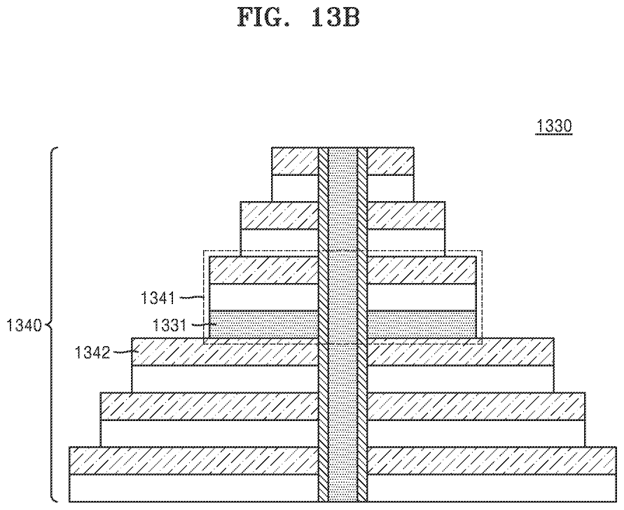

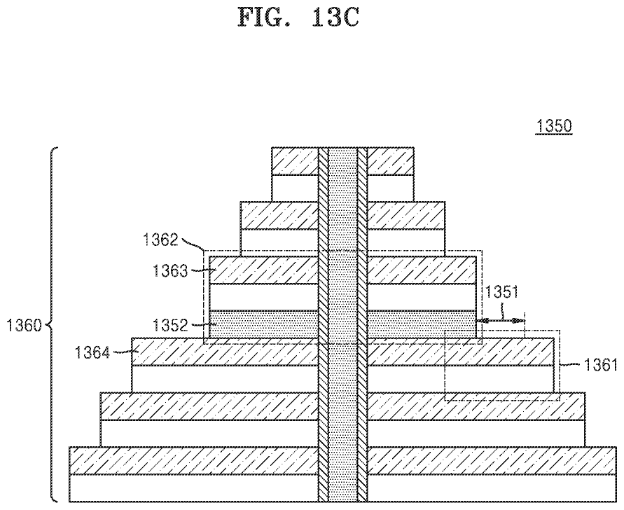

When only determining the horizontal size of the lower word line group 1230 to include the etch stopper distance 1250 is performed in operation S1110, a completed three-dimensional flash memory is as illustrated in FIG. 13A. When only arranging the etch stopper protection layer 1260 between the upper word line group 1220 and the lower word line group 1230 is performed in operation S1110, a completed three-dimensional flash memory is as illustrated in FIG. 13B. When both the determining the horizontal size of the lower word line group 1230 to include the etch stopper distance 1250 and the arranging the etch stopper protection layer 1260 between the upper word line group 1220 and the lower word line group 1230 are performed in operation S1110, a completed three-dimensional flash memory is as illustrated in FIG. 13C. This will be described in further detail below.

Next, in operation S1140, the manufacturing system may remove the photoresists 1270, 1280 as illustrated in FIG. 12K to complete the manufacture of a three-dimensional flash memory including the word lines 1210 having a stair shape.

FIGS. 13A through 13C illustrate a three-dimensional flash memory manufactured using the method of manufacturing a three-dimensional flash memory, described with reference to FIG. 11.

Referring to FIG. 13A, a three-dimensional flash memory 1310 according to an embodiment includes word lines having a step and manufactured in operations S1110 through S1130 described above with reference to FIGS. 11 through 12F. In detail, as the manufacturing system determines a horizontal size of a lower word line group to include an etch stopper distance 1311 in operation S1110, while a stair shape having an equally spaced width and an equally spaced height is formed using a plurality of word lines 1320, the three-dimensional flash memory 1310 includes a portion 1321 that has a different width from other portions of the stair shape.

That is, the portion 1321 having a different width from the other portions may be formed by the etch stopper distance 1311 for preventing unnecessary etching of a lowermost word line 1322 included in an upper word line group from among the plurality of word lines 1320 in a process of performing an etching operation on the plurality of word lines 1320.

Referring to FIG. 13B, a three-dimensional flash memory 1330 according to another embodiment includes word lines having a stair shape and manufactured in operations S1110 through S1130 described above with reference to FIGS. 11 through 12F. In particular, as the manufacturing system arranges an etch stopper protection layer 1331 between an upper word line group and a lower word line group in operation S1110, while a stair shape having an equally spaced width and an equally spaced height is formed using a plurality of word lines 1340, the three-dimensional flash memory 1310 includes a portion 1341 that has a different height from other portions of the stair shape.

That is, the portion 1341 having a different height from the other portions may be formed by the etch protection layer 1331 for preventing unnecessary etching of an uppermost word line 1342 included in a lower word line group from among the plurality of word lines 1340 in a process of performing an etching operation on the plurality of word lines 1340.

Referring to FIG. 13C, a three-dimensional flash memory 1350 according to an embodiment includes word lines having a stair shape and manufactured in operations S1110 through S1130 described above with reference to FIGS. 11 through 12F. In particular, as the manufacturing system has arranged an etch stopper protection layer 1352 between an upper word line group and a lower word line group at the same time as determining a horizontal size of the lower word line group to include an etch stopper distance 1351, in operation S1110, while a stair shape having an equally spaced width and an equally spaced height is formed using a plurality of word lines 1360, the three-dimensional flash memory 1350 includes a portion 1361 having a different width and a portion 1362 having a different height from other portions of the stair shape.

The portion 1361 having a different width may be formed by the etch stopper distance 1351 for preventing unnecessary etching of a lowermost word line 1363 included in the upper word line group from among the plurality of word lines 1360 in a process of performing an etching operation on the plurality of word lines 1360, and the portion 1362 having a different height may be formed by the etch stopper protection layer 1352 for preventing unnecessary etching of an uppermost word line 1364 included in the lower word line group from among the plurality of word lines 1360 in a process of performing an etching operation on the plurality of word lines 1360.

As described above, according to the method of manufacturing a three-dimensional flash memory of the embodiment, when manufacturing a three-dimensional flash memory including word lines in a total of six steps, an etching operation is performed only twice (an etching operation is performed five times in a method of manufacturing a three-dimensional flash memory according to the related art), and thus, the number of repetitions of an etching operation may be remarkably reduced, thus simplifying the manufacturing process.

While the inventive concept has been particularly shown and described with reference to examples thereof, it will be understood by those of ordinary skill in the art that various changes in form and details may be made therein without departing from the spirit and scope of the inventive concept as defined by the following claims. For example, an appropriate result may be attained even when the above-described techniques are performed in a different order from the above-described method, and/or components, such as the above-described system, structure, device, and circuit, are coupled or combined in a different form from the above-described methods or substituted for or replaced by other components or equivalents thereof.

Therefore, other implementations, other embodiments and claims and equivalents also fall within the scope of the claims described below.

1. A three-dimensional flash memory for achieving integration, the three-dimensional flash memory comprising:
at least one memory cell string extending vertically and comprising at least one channel layer and at least one charge storage layer surrounding the at least one channel layer; and
a plurality of word lines that are orthogonally connected to the at least one memory cell string and stacked and extend in a horizontal direction, wherein the plurality of word lines extend by different lengths from each other to form a stair shape including a stepped portion and a plane portion,
wherein the at least one memory cell string is formed in both the plane portion and the stepped portion.

2. The three-dimensional flash memory of claim 1, wherein a contact of each of the plurality of word lines is formed only in a minimized partial region of each of a plurality of steps of the stepped portion.

3. The three-dimensional flash memory of claim 2, wherein the minimized partial region comprises a region corresponding to a cross-sectional area of the contact of each of the plurality of word lines.

4. The three-dimensional flash memory of claim 1, wherein the at least one memory cell string formed in the stepped portion is located in a same column as a contact of each word line, formed in the stepped portion, for each of steps of the stepped portion.

5. A three-dimensional flash memory for achieving integration, the three-dimensional flash memory comprising:
at least one memory cell string extending in a direction and comprising at least one channel layer and at least one charge storage layer surrounding the at least one channel layer; and
a plurality of word lines vertically connected to the at least one memory cell string,
wherein a contact of each of the plurality of word lines is formed only in a minimized partial region of the entire region of each of the plurality of word lines.

6. The three-dimensional flash memory of claim 5, wherein the plurality of word lines provide a space where at least one other memory cell string that is not arranged in a same array as the at least one memory cell string is formed, as the contact of each of the plurality of word lines is formed only in a minimized partial region of the entire region of each of the plurality of word lines.

7. The three-dimensional flash memory of claim 6, wherein the plurality of word lines are shared by the at least one memory cell string and the at least one other memory cell string as the at least one other memory cell string is formed in the space.

8. The three-dimensional flash memory of claim 6, wherein the minimized partial region where the contact of each of the plurality of word lines is formed comprises a region located in a same row as the entire region of each of the plurality of word lines.

9. A method of manufacturing a three-dimensional flash memory, for efficiently forming word lines, the method comprising:
preparing a plurality of word lines stacked in a horizontal direction by dividing the plurality of word lines into an upper word line group and a lower word line group, wherein the upper word line group and the lower word line group have different horizontal sizes and are stacked in order in a stair shape such that at least a portion of an upper surface of each of the upper and lower word line groups is exposed;
forming photoresists on at least a portion of the upper surface of the upper word line group and at least a portion of the upper surface of the lower word line group; and
simultaneously performing an etching operation on each of the upper word line group and the lower word line group, on which the photoresists are formed.

10. The method of claim 9, wherein the lower word line group has a greater horizontal size than the upper word line group.

11. The method of claim 9, wherein the preparing of the plurality of word lines by dividing the plurality of word lines into an upper word line group and a lower word line group comprises determining a horizontal size of the lower word line group to include an etch stopper distance to prevent etching of a lowermost word line of the upper word line group when an etching operation is performed on the lower word line group.

12. The method of claim 9, wherein the preparing of the plurality of word lines by dividing the plurality of word lines into an upper word line group and a lower word line group comprises arranging an etch stopper protection layer between the upper word line group and the lower word line group to prevent etching of an uppermost word line of the lower word line group when an etching operation is performed on the upper word line group.

13. The method of claim 9, wherein the simultaneously performing of an etching operation on each of the upper word line group and the lower word line group is repeatedly performed based on a number of steps whereby word lines included in the upper word line group are stacked and a number of steps whereby word lines included in the lower word line group are stacked.
